(19) United States
(12) Patent Application Publication
(10) Pub. No.: US 2025/0199316 A1
(43) Pub. Date: Jun. 19, 2025

(54) HEAD-UP DISPLAY DEVICE AND TEMPERATURE CONTROL METHOD THEREOF

(71) Applicant: Coretronic Corporation, Hsin-Chu (TW)

(72) Inventors: Yu-Wei Guo, Hsin-Chu (TW); Wen-Yen Chung, Hsin-Chu (TW)

(73) Assignee: Coretronic Corporation, Hsin-Chu (TW)

(21) Appl. No.: 18/983,374

(22) Filed: Dec. 17, 2024

(30) Foreign Application Priority Data
Dec. 19, 2023 (CN) 202311765417.2

(51) Int. Cl. G02B 27/01

(52) U.S. Cl. CPC G02B 27/0172; G02B 27/0176; G02B 2027/0138; G02B 2027/014; G02B 2027/0154

(57) ABSTRACT

A head-up display device includes a processing unit and an imaging unit. The imaging unit includes a light source module, an optical modulation module, a circuit board, and a plurality of first temperature sensors. The circuit board surrounds the optical modulation module. The plurality of first temperature sensors are disposed on the circuit board. The circuit board is electrically connected to the plurality of first temperature sensors and the optical modulation module. The processing unit is electrically connected to the light source module and the circuit board to obtain a plurality of temperatures from the plurality of first temperature sensors. When a highest temperature of the plurality of temperatures is greater than a threshold value, the processing unit is adapted to enable the light source module to reduce an intensity of the illumination light beam. A temperature control method of a head-up display device is also proposed.

### CROSS-REFERENCE TO RELATED APPLICATION

This application claims the priority benefit of China application serial no. 202311765417.2, filed on Dec. 19, 2023. The entirety of the above-mentioned patent application is hereby incorporated by reference herein and made a part of this specification.

### BACKGROUND

### Technical Field

The disclosure relates to a display device, and particularly relates to a head-up display device and temperature control method thereof.

### Description of Related Art

The head-up display device allows the driver to see displayed information through the windshield without changing his or her line of sight. In order to achieve the above purpose, it is necessary to use a reflector to transmit the image light beam to the windshield and to the driver's eyes. However, ambient light beams (such as sunlight) may also irradiate the head-up display device via the reflector, resulting in crashes or even permanent damage as a result of excessive temperature of the display device.

The information disclosed in this Background section is only for enhancement of understanding of the background of the described technology and therefore it may contain information that does not form the prior art that is already known to a person of ordinary skill in the art. Further, the information disclosed in the Background section does not mean that one or more problems to be resolved by one or more embodiments of the invention was acknowledged by a person of ordinary skill in the art.

### SUMMARY

The disclosure provides a head-up display device, which can effectively control the temperature of the head-up display device and extend the service life of the head-up display device. The head-up display device has a smaller volume and lower manufacturing cost.

The disclosure provides a temperature control method of a head-up display device, which can effectively control the temperature of the head-up display device to ensure its normal display function and extend the service life of the head-up display device.

Other objects and advantages of the disclosure can be further understood from the technical features disclosed in the disclosure.

In order to achieve one or a portion of or all of the above objectives or other objectives, an embodiment of the disclosure provides a head-up display device includes a processing unit and an imaging unit of a. The imaging unit includes a light source module, an optical modulation module, a circuit board, and a plurality of first temperature sensors. The optical modulation module is configured to convert an illumination light beam emitted by the light source module into an image light beam. The circuit board surrounds the optical modulation module. The plurality of first temperature sensors are disposed on the circuit board. The circuit board is electrically connected to the plurality of first temperature sensors and the optical modulation module. The processing unit is electrically connected to the light source module and the circuit board to obtain a plurality of temperatures from the plurality of first temperature sensors. When a highest temperature of the plurality of temperatures is greater than a threshold value, the processing unit is adapted to enable the light source module to reduce an intensity of the illumination light beam.

In an embodiment of the disclosure, the head-up display device further includes a reflecting mirror group disposed on a transmission path of the image light beam. The reflecting mirror group includes at least one reflecting mirror and at least one driving component. The at least one driving component is electrically connected to the processing unit, and the at least one driving component is connected to the at least one reflecting mirror.

In an embodiment of the disclosure, when the highest temperature is greater than the threshold value and the intensity of the illumination light beam is 0, the processing unit is adapted to enable the at least one driving component to change a rotation angle or position of the at least one reflecting mirror.

In an embodiment of the disclosure, the threshold value includes a first threshold value and a second threshold value. The second threshold value is greater than the first threshold value. The processing unit is also adapted to generate an average temperature based on the plurality of temperatures, and determine whether a difference between the highest temperature and the average temperature is greater than a preset value. When the difference between the highest temperature and the average temperature is less than or equal to the preset value, and the highest temperature is greater than the first threshold value, the processing unit is adapted to enable the light source module to reduce the intensity of the illumination light beam.

In an embodiment of the disclosure, when the difference between the highest temperature and the average temperature is greater than the preset value, and the highest temperature is greater than the second threshold value, the processing unit is adapted to enable the light source module to reduce the intensity of the illumination light beam.

In an embodiment of the disclosure, the head-up display device further includes a second temperature sensor configured to sense an ambient temperature. The second temperature sensor is electrically connected to the processing unit. The threshold value also includes a third threshold value, and the third threshold value corresponds to the ambient temperature.

In an embodiment of the disclosure, when the difference between the highest temperature and the average temperature is less than or equal to the preset value, the processing unit is also adapted to determine whether the highest temperature is greater than the third threshold value. When the highest temperature is greater than the third threshold value, and the highest temperature is greater than the first threshold value, the processing unit is adapted to enable the light source module to reduce the intensity of the illumination light beam.

In an embodiment of the disclosure, when the difference between the highest temperature and the average temperature is less than or equal to the preset value, and the highest temperature is less than the third threshold value, the intensity of the illumination light beam is not reduced.

In an embodiment of the disclosure, a shape of the circuit board is an annular square, and the plurality of first temperature sensors are disposed on four sides of the circuit board.

In an embodiment of the disclosure, the head-up display device further includes a case with an opening. The opening exposes at least a portion of the optical modulation module, and the plurality of first temperature sensors are located between the case and the circuit board.

In an embodiment of the disclosure, the plurality of first temperature sensors of the head-up display device are located between the light source module and the circuit board, or the circuit board is located between the light source module and the plurality of first temperature sensors.

An embodiment of the disclosure provides a temperature control method of a head-up display device. The head-up display device includes a processing unit and an imaging unit. The imaging unit includes a light source module, an optical modulation module, a circuit board, and a plurality of first temperature sensors. The circuit board surrounds the optical modulation module and the plurality of first temperature sensors are disposed on the circuit board. The method includes the following steps. A plurality of temperatures of the plurality of first temperature sensors are obtained by the processing unit, and a highest temperature is obtained from the plurality of temperatures. In response to the highest temperature being greater than a threshold value, an intensity of an illumination light beam is reduced by the light source module. In response to the highest temperature being less than or equal to the threshold value, the intensity of the illumination light beam is not reduced.

In an embodiment of the disclosure, the temperature control method further includes the following steps. In response to the highest temperature being greater than the threshold value and the intensity of the illumination light beam being 0, a rotation angle or position of at least one reflecting mirror is changed by at least one driving component.

In an embodiment of the disclosure, the threshold value of the temperature control method includes a first threshold value and a second threshold value. The second threshold value is greater than the first threshold value. The method also includes the following steps. An average temperature is generated according to the plurality of temperatures by the processing unit, and whether a difference between the highest temperature and the average temperature is greater than a preset value is determined. The step of reducing the intensity of the illumination light beam through the light source module also includes reducing the intensity of the illumination light beam through the light source module in response to the difference between the highest temperature and the average temperature being less than or equal to the preset value, and the highest temperature being greater than the first threshold value.

In an embodiment of the disclosure, the step of reducing the intensity of the illumination light beam through the light source module further includes: in response to the difference between the highest temperature and the average temperature being greater than the preset value, and the highest temperature being greater than the second threshold value, reducing the intensity of the illumination light beam through the light source module.

In an embodiment of the disclosure, the threshold value also includes a third threshold value. The third threshold value corresponds to an ambient temperature. The method also includes the following steps. Whether the highest temperature is greater than the third threshold value is determined by the processing unit. The step of reducing the intensity of the illumination light beam through the light source module also includes: in response to the highest temperature being greater than the third threshold value, and the highest temperature being greater than the first threshold value, reducing the intensity of the illumination light beam through the light source module.

In an embodiment of the disclosure, the step of not reducing the intensity of the illumination light beam includes: in response to the difference between the highest temperature and the average temperature being less than or equal to the preset value, and the highest temperature being less than a third threshold value, the intensity of the illumination light beam is not reduced.

According to the above, the head-up display device and the temperature control method thereof according to embodiments of the disclosure use the circuit board to surround the optical modulation module, and use the temperature sensors on the circuit board to sense the temperature of the optical modulation module, which can reduce the volume of the head-up display device. On the other hand, since the temperature of the optical modulation module is sensed more accurately, when the temperature of the first temperature sensor exceeds the set threshold value, the light intensity of the light source module can be correspondingly reduced to ensure the safe operation of the optical modulation module while preventing over-protection or error from occurring, which can also extend the use time of the optical modulation module.

In order to make the above-mentioned features and advantages of the disclosure clearer and easier to understand, the following embodiments are given and described in details with accompanying drawings as follows.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic structural diagram of a head-up display device according to an embodiment of the disclosure.

FIG. 2A is a detailed structural diagram of a head-up display device according to an embodiment of the disclosure.

FIG. 2B to FIG. 2D are schematic top diagrams of a light spot distribution formed after an optical modulation module is irradiated with ambient light according to an embodiment of the disclosure.

FIG. 2E is a schematic distribution diagram of a plurality of first temperature sensors according to some embodiments of the disclosure.

FIG. 3 is a schematic flowchart of a temperature control method of a head-up display device according to an embodiment of the disclosure.

FIG. 4 is a schematic flowchart of a temperature control method of a head-up display device according to another embodiment of the disclosure.

FIG. 5 is a schematic flowchart of a temperature control method of a head-up display device according to yet another embodiment of the disclosure.

### DESCRIPTION OF THE EMBODIMENTS

In the following detailed description of the preferred embodiments, reference is made to the accompanying drawings which form a part hereof, and in which are shown by way of illustration specific embodiments in which the invention may be practiced. In this regard, directional terminology, such as “top,” “bottom,” “front,” “back,” etc., is used with reference to the orientation of the Figure(s) being described. The components of the present invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

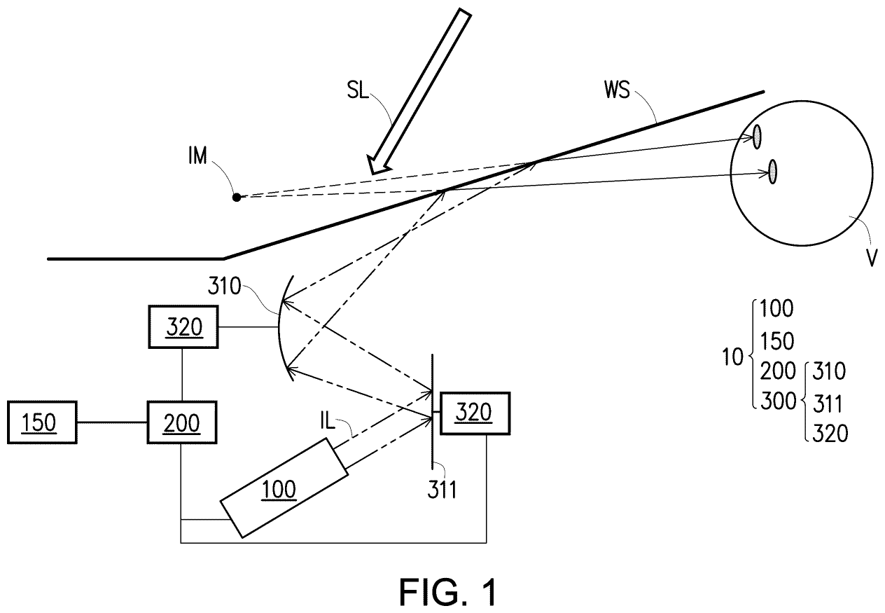

FIG. 1 is a schematic structural diagram of a head-up display device according to an embodiment of the disclosure. Referring to FIG. 1 first, a head-up display device 10 includes an imaging unit 100, a processing unit 200, and a reflecting mirror group 300. The reflecting mirror group 300 may include a reflecting mirror 310, a reflecting mirror 311, and two driving components 320 that connect the reflecting mirror 310 and the reflecting mirror 311 respectively. The imaging unit 100 is configured to emit an image light beam IL and reflect the image light beam IL to a windshield WS using the reflecting mirror 310 and the reflecting mirror 311. The windshield WS can reflect the image light beam IL into a viewer V's field of view, and display a virtual image in front of the viewer V's eyes. For example, the viewer V can observe the virtual image formed by the image light beam IL, such as an image IM, on the side of the windshield WS facing away from the viewer V (for example, outside the car). The image IM may be driving information, road condition information, or other information, and the disclosure is not limited thereto.

The processing unit 200 can be electrically connected to the driving component 320. The driving component 320 can be a motor, for example, and is equipped with a plurality of gears, slide rails, or connecting rods (not shown) to mechanically connect the reflecting mirror 310 and the reflecting mirror 311, thereby controlling the reciprocating movement or rotation of the reflecting mirror 310 and/or the reflecting mirror 311, so that the movement of the reflecting mirror 310 and/or the reflecting mirror 311 can change the transmission direction of the image light beam IL, so as to adjust the position of the image IM viewed by the viewer V. In an embodiment, the reflecting mirror 310 and the reflecting mirror 311 may respectively be one of a plane mirror, a convex reflecting mirror, and a concave reflecting mirror. In FIG. 1, two driving components 320 and two reflecting mirrors 310 and 311 are taken as an example. In other embodiments, the number of the driving component 320 and the reflecting mirrors 310 and 311 can be adjusted according to actual requirements. For example, only a single driving component 320 is disposed to connect two reflecting mirrors 310 and 311 at the same time.

When the ambient light is excessively bright, for example, a solar light beam SL of the environment where the viewer V or the vehicle is located is too bright, the solar light beam SL may be reflected by the reflecting mirror 310 and/or the reflecting mirror 311 to the imaging unit 100 after passing through the windshield SW. The temperature of the imaging unit 100 will rise after the imaging unit 100 is continuously irradiated with the solar light beam SL. When the temperature rises to exceed the operating temperature specification of the imaging unit 100, the imaging unit 100 may shut down, components may be damaged, or permanent damage may occur.

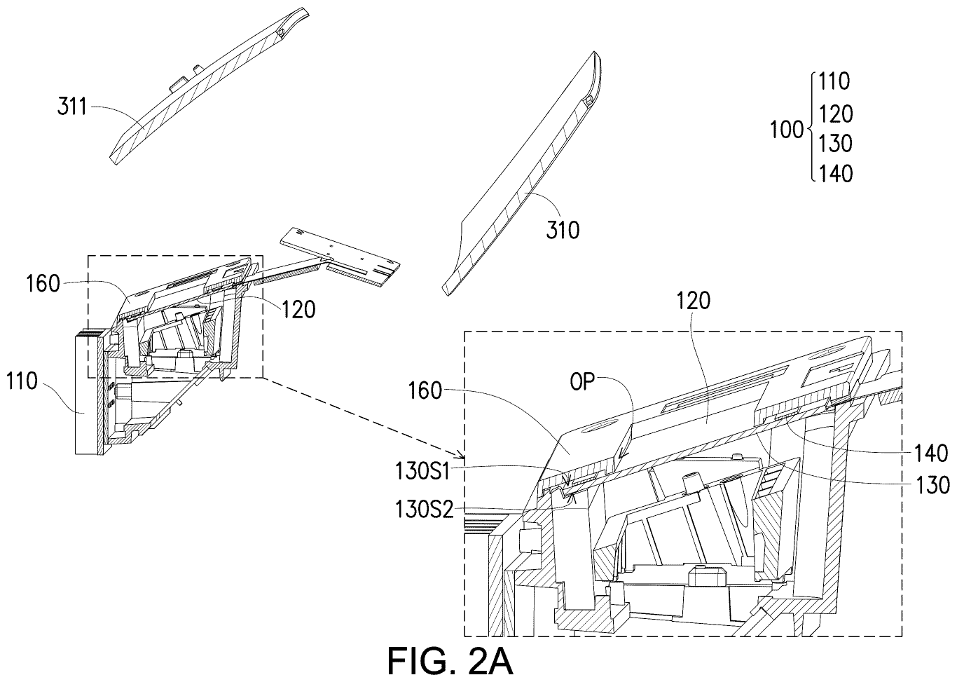

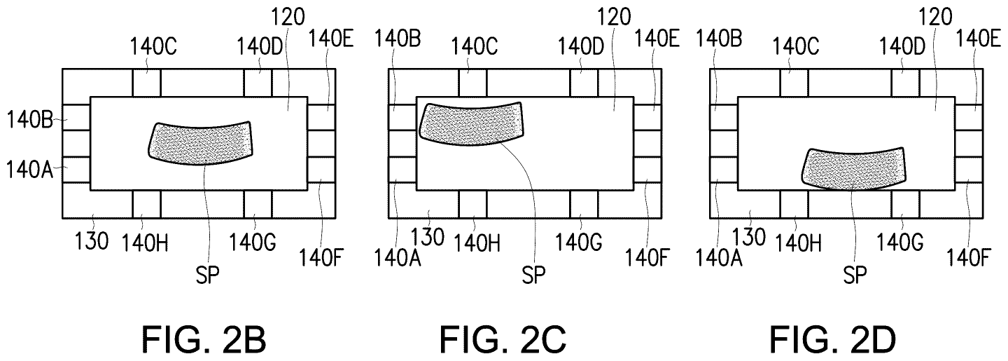

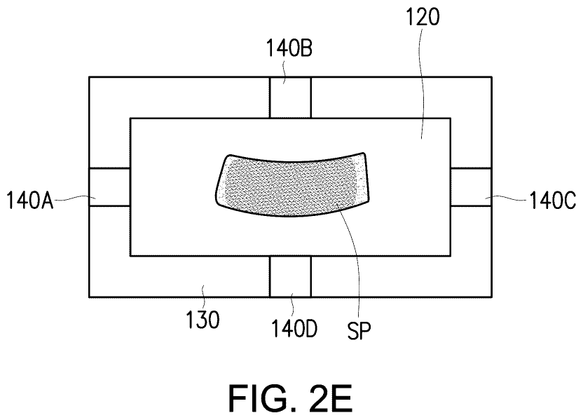

FIG. 2A is a detailed structural diagram of a head-up display device according to an embodiment of the disclosure. Referring to FIG. 1 and FIG. 2A at the same time, in the embodiment, the imaging unit 100 may include, for example, a light source module 110, an optical modulation module 120, a circuit board 130, and a plurality of first temperature sensors 140. The light source module 110 is configured to provide an illumination light beam (not shown), and the optical modulation module 120 is disposed on the transmission path of the illumination light beam to convert the illumination light beam into the image light beam IL. The optical modulation module 120 and the plurality of first temperature sensors 140 can be disposed on the circuit board 130, and the circuit board 130 and the plurality of first temperature sensors 140 are disposed around the optical modulation module 120. The plurality of first temperature sensors 140 of the embodiment are not located on the transmission paths of the illumination light beam and the image light beam IL.

The light source module 110 may include components such as light sources and light guide components. The light sources may be light emitting diodes (LED) or laser diodes (LD) or a combination of the above. The optical modulation module 120 is, for example, a transparent liquid crystal panel, an electro-optical modulator, a magneto-optic modulator, an acousto-optic modulator (AOM), a reflective liquid crystal on silicon (LCOS), or a digital micro-mirror device (DMD).

The circuit board 130 includes a variety of signal lines (such as data lines, scan lines, or power lines, not shown), a plurality of pads (not shown), and at least one driving circuit chip (not shown). The driving circuit chip has, for example, transistors or integrated circuits (ICs), and can be electrically connected to the plurality of first temperature sensors 140 and the optical modulation module 120, and control the display signal of the optical modulation module 120 to provide a display image. The circuit board 130 is, for example, a printed circuit board (PCB). In some embodiments, the circuit board 130 may also be a combination of a glass substrate and a pixel circuit layer. The pixel circuit layer is formed on the glass substrate using a semiconductor process, and the pixel circuit layer may include active components (such as thin film transistors) and a variety of signal lines (such as data lines, scan lines, or power lines).

The processing unit 200 is electrically connected to the light source module 110 and the circuit board 130, and can be electrically connected to the optical modulation module 120 and the plurality of first temperature sensors 140 via the circuit board 130. The processing unit 200 is configured to obtain a plurality of temperature values sensed by the plurality of first temperature sensors 140. The processing unit 200 may include a plurality of processors. The processors are, for example, central processing units (CPUs) or other programmable general-purpose or special-purpose micro control units (MCUs), microprocessors, digital signal processors (DSPs), programmable controllers, application specific integrated circuits (ASICs), arithmetic logic units (ALUs), complex programmable logic devices (CPLDs), field programmable gate arrays (FPGAs), or other similar elements, or a combination thereof. In an embodiment, each function of the processing unit 200 may be implemented as a plurality of program codes. These program codes will be stored in a memory, and the processing unit 200 will execute these program codes. Alternatively, in an embodiment, each function of the processing unit 200 may be implemented as one or more circuits. The disclosure is not limited to using software or hardware to implement each function of the processing unit 200.

The processing unit 200 can set a threshold value for the temperatures sensed by the plurality of first temperature sensors 140, and sense the temperature everywhere around the optical modulation module 120 via the plurality of first temperature sensors 140, so as to monitor the temperature of the optical modulation module 120. When the optical modulation module 120 is irradiated with the solar light beam SL such that the temperature of the optical modulation module 120 is excessively high, or when the optical modulation module 120 is overheated due to an increase in the ambient temperature, and the highest temperature among the plurality of temperatures sensed by the plurality of first temperature sensors 140 is greater than the aforementioned threshold value, the light source module 110 can be controlled via the processing unit 200 to reduce the intensity of the illumination light beam, so as to reduce the temperature of the optical modulation module 120. The method of reducing the intensity of the illumination light beam through the light source module 110 is, for example, by reducing the driving current, driving voltage, or power of the light source module 110 to reduce the intensity of the illumination light beam, thereby reducing the heat absorbed by the optical modulation module 120 to facilitate heat dissipation and cooling of the optical modulation module 120.

In the embodiment, since the plurality of first temperature sensors 140 are not located on the transmission path of the image light beam IL, they will not block the light path of the image light beam IL. On the other hand, the costs and volumes of the plurality of first temperature sensors 140 are less than the costs and volumes of infrared sensors, and there is no need to dispose additional infrared reflecting mirrors to correspondingly adjust the light path of infrared light. Therefore, compared with the sensing method of the conventional technology that uses infrared sensors to sense whether the solar light beam SL irradiates the optical modulation module 120, the optical system design of the embodiment is relatively simple and conducive to reducing the accommodation space and production cost of the head-up display device 10, and the optical efficiency will not be reduced by disposing the infrared reflecting mirrors, thus further improving the competitiveness of the product.

In an embodiment, the plurality of first temperature sensors 140 can be blocked by a light shield member to prevent the solar light beam SL or ambient light from irradiating the first temperature sensors 140, resulting in misjudgment by the processing unit 200 as a result of a rise in the temperatures of the first temperature sensors 140. For example, the head-up display device 10 may further include a case 160 disposed on the plurality of first temperature sensors 140 to shield the plurality of first temperature sensors 140, and the case 160 covers at least a portion of the circuit board 130. In order not to block the light emitting light path of the image light beam IL, the case 160 may have an opening OP. The opening OP is configured to expose at least a portion of the optical modulation module 120.

In the embodiment shown in FIG. 2B, the plurality of first temperature sensors 140 are located between the case 160 and the circuit board 130, and the circuit board 130 is located between the light source module 110 and the plurality of first temperature sensors 140. For example, the plurality of first temperature sensors 140 are disposed on a surface 130S1 of the circuit board 130 facing the case 160. In some embodiments, the plurality of first temperature sensors 140 may be disposed on a surface 130S2 of the circuit board 130 facing away from the case 160. The plurality of first temperature sensors 140 may be located between the light source module 110 and the circuit board 130.

FIG. 2B to FIG. 2D are schematic top diagrams of a light spot distribution formed after an optical modulation module is irradiated with ambient light according to an embodiment of the disclosure. The optical modulation module 120 may include a panel. The panel corresponds to the area where the optical modulation module 120 configured to convert the illumination light beam into the image light beam IL. The shape of the panel is, for example, a rectangle. Referring to FIG. 2A to FIG. 2D at the same time, viewing from a direction perpendicular to the panel, when the solar light beam SL irradiates the optical modulation module 120, a light spot SP will be formed on the optical modulation module 120. As shown in FIG. 2B, the light spot SP can be formed, for example, at the center of the panel of the optical modulation module 120. At this time, the first temperature sensors 140A to 140H disposed adjacent to the optical modulation module 120 will sense similar temperatures. The processing unit 200 can determine that the light spot SP is located at the center of the panel of the optical modulation module 120 at this time according to the temperatures sensed by the first temperature sensors 140A to 140H.

As shown in FIG. 2C, the light spot SP is formed, for example, at the upper left corner of the panel of the optical modulation module 120. The temperatures of the first temperature sensors 140B and 140C will be greater than the temperatures of the first temperature sensors 140A, 140D, and 140E. The processing unit 200 can determine that the light spot SP is located at a position adjacent to the periphery of the panel of the optical modulation module 120 at this time.

As shown in FIG. 2D, the light spot SP is formed, for example, at the bottom of the panel of the optical modulation module 120. The temperatures of the first temperature sensors 140H and 140G will be greater than the temperatures of the first temperature sensors 140A to 140F. The processing unit 200 can determine that the light spot SP is located adjacent to one side of the optical modulation module 120 at this time. Accordingly, when the solar light beam SL irradiates different positions of the optical modulation module 120, the processing unit 200 can determine whether the light spot SP is formed at the center or periphery of the panel of the optical modulation module 120 according to the above principle.

FIG. 2E is a schematic distribution diagram of a plurality of first temperature sensors according to some embodiments of the disclosure. Referring to FIG. 2E, the outline of the optical modulation module 120 may correspond to the outline of the circuit board 130. In some embodiments, the outline of the optical modulation module 120 may be rectangular, and the shape of the circuit board 130 may be a ring-shaped square, and the first temperature sensors 140A, 140B, 140C, and 140D may surround four sides of the circuit board 130. In some embodiments, the first temperature sensors 140A to 140D may respectively contact four sides of the optical modulation module 120. In other embodiments, the optical modulation module 120 and the circuit board 130 may also have other shapes. In other embodiments, only two first temperature sensors 140 may be disposed adjacent to two ends of the diagonal line of the optical modulation module 120, or adjacent to two sides of the long side of the optical modulation module 120, for example, at the positions of the first temperature sensors 140A and 140C in FIG. 2E.

TABLE 1

| | | | | Light spot at a | | | Light spot at a | | |
|---|---|---|---|---|---|---|---|---|---|
| | No light spot | | | center | | | periphery | | |
| State | Tb3 | Ts | Tp | Tb1 | Ts | Tp | Tb2 | Ts | Tp |
| Te25 | 35 | 35 | 45 | 85 | 40 | 60 | 100 | 55 | 60 |
| Te55 | 65 | 65 | 75 | | 70 | 90 | | 85 | 90 |
| Te70 | 80 | 80 | 90 | | 85 | 105 | | 100 | 105 |
| Te75 | 85 | 85 | 95 | | 90 | 110 | | 105 | 110 |
| Te85 | 95 | 95 | 105 | | 100 | 120 | | 115 | 120 |

Table 1 above shows the relationship between the threshold value and the temperature of the head-up display device in the temperature control method of the head-up display device according to an embodiment of the disclosure. The unit of the values in Table 1 is Celsius (° C.). The temperatures sensed by the plurality of first temperature sensors 140, the temperature of the optical modulation module 120, and the determination method of the processing unit 200 will be further described below. Referring to Table 1, when the light spot SP is at the center of the shape of the optical modulation module 120 (as shown in FIG. 2B), the relationship between a highest temperature Ts sensed among the plurality of temperatures of the plurality of first temperature sensors 140 and a panel temperature Tp of the optical modulation module 120 at this time can be known from the comparison table of Table 1. The comparison table is obtained, for example, from experimental or simulated data. For example, when the highest temperature Ts is 70 degrees (the unit is Celsius, ° C.), the panel temperature Tp is 90 degrees. The specification temperature of the optical modulation module 120 is, for example, 105 degrees, which means that when the panel temperature Tp exceeds 105 degrees, it may affect the normal operation of the optical modulation module 120. At this time, the corresponding highest temperature Ts is 85 degrees. The processing unit 200 can set a first threshold value Tb1 to 85 degrees. In other embodiments, different optical modulation modules 120 can correspond to different specification temperatures, and different values of the first threshold value Tb1 can also be set.

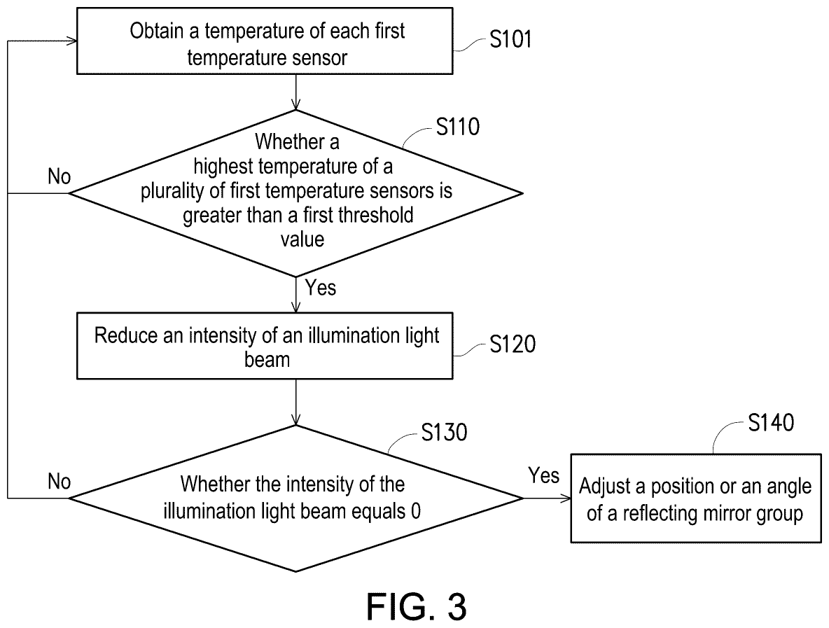

FIG. 3 is a schematic flowchart of a temperature control method of a head-up display device according to an embodiment of the disclosure. Referring to Table 1 and FIG. 3 at the same time, in step S101, the processing unit 200 obtains the plurality of temperatures of the plurality of first temperature sensors 140. In step S110, it may be determined whether the highest temperature Ts among the plurality of temperatures of the plurality of first temperature sensors 140 is greater than the first threshold value Tb1. If the highest temperature Ts is less than or equal to the first threshold value Tb1, the intensity of the illumination light beam of the light source module 110 is not reduced; if so, it means that the panel temperature Tp is too high, and step S120 can be performed. The processing unit 200 reduces the intensity of the illumination light beam through the light source module 110, for example, by reducing the luminous power of the light source module 110 to reduce the intensity of the illumination light beam, so that the light energy transmitted to the optical modulation module 120 may be reduced and excessive temperature of the optical modulation module 120 may be avoided.

In step S130, the processing unit 200 determines whether the intensity of the illumination light beam is 0, which can be known, for example, by determining whether the power of the light source module 110 has been reduced to 0. If not, return to step S101; if so, then step S140 is performed, and the processing unit 200 may be adapted to enable the driving component 320 to change the rotation angle or position of the reflecting mirror 310, or enable the driving component 320 to change the rotation angle or position of the reflecting mirror 311. This prevents the light spot SP formed by the solar light beam SL from continuing to form on the optical modulation module 120, which is conducive to cooling the optical modulation module 120. After the processing unit 200 confirms that the temperatures sensed by the first temperature sensors 140 drop back to a safe temperature, the processing unit 200 can restart the light source module 110, so that the optical modulation module 120 emits the image light beam IL. The reflecting mirror 310 or the reflecting mirror 311 are adjusted back to the light path of the image light beam IL or to its original angle, so that the image light beam IL can be transmitted to the viewer V, and the process can return to step S101. Accordingly, the head-up display device 10 can achieve favorable temperature control.

In some embodiments, continuing to refer to Table 1, when the light spot SP is at the peripheral position of the optical modulation module 120 (as shown in FIG. 2C and FIG. 2D), it can be known from the comparison table in Table 1 the relationship between the highest temperature Ts sensed by the plurality of first temperature sensors 140 and the panel temperature Tp of the optical modulation module 120 at this time. For example, when the highest temperature Ts is 55 degrees, since the light spot SP is adjacent to the first temperature sensors 140, there is not much difference between the panel temperature Tp and the highest temperature Ts (for example, the panel temperature Tp is 60 degrees). The specification temperature of the optical modulation module 120 is, for example, 105 degrees, which means that when the panel temperature Tp exceeds 105 degrees, it may affect the normal operation of the optical modulation module 120. At this time, the corresponding highest temperature Ts is 100 degrees, and the processing unit 200 can set a second threshold value Tb2 that is greater than the first threshold value Tb1. For example, the second threshold value Tb2 is set to 100 degrees. In other embodiments, the second threshold value Tb2 can also be set to different values.

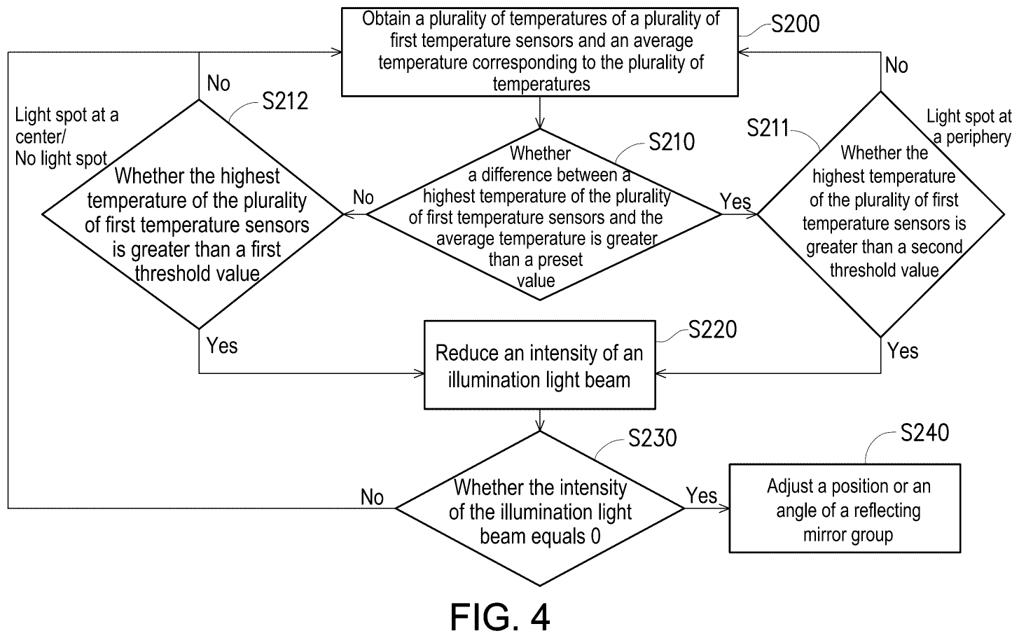

FIG. 4 is a schematic flowchart of a temperature control method of a head-up display device according to another embodiment of the disclosure. Referring to Table 1 and FIG. 4 at the same time, in step S200, the processing unit 200 obtains the plurality of temperatures of the plurality of first temperature sensors 140 and obtains the average temperature corresponding to the plurality of temperatures.

In step S210, the processing unit 200 may determine whether the difference between the highest temperature Ts and the average temperature is greater than a preset value. The preset value is, for example, any temperature from 1 to 10 degrees, in which the unit is Celsius (° C.). In the embodiment, the preset value is, for example, 5 degrees. If not, it means that the plurality of first temperature sensors 140 sense substantially similar temperature values, and the light spot SP is formed at the center of the panel of the optical modulation module 120 (as shown in FIG. 2B) or there is no light spot SP formed on the optical modulation module 120 at this time. The processing unit 200 may respond to this determination by performing step S212 to determine whether the highest temperature Ts is greater than the first threshold value Tb1. If not, return to step S200, and the intensity of the illumination light beam of the light source module 110 is not reduced; if so, proceed to step S220 to reduce the power of the light source module 110, so as to reduce the intensity of the illumination light beam and allow the optical modulation module 120 to effectively cool down. Step S230 may be further performed to determine whether the intensity of the illumination light beam of the light source module 110 has been reduced to 0 and the highest temperature Ts is still greater than the first threshold value Tb1. If not, return to step S200; if so, proceed to step S240, and the processing unit 200 may be adapted to enable the driving component 320 to change the rotation angle or position of the reflecting mirror 310 or the reflecting mirror 311. For the descriptions of relevant steps or methods, reference may be made to the aforementioned step S130 and step S140, which will not be repeated here.

In step S210, if the difference between the highest temperature Ts and the average temperature is greater than the preset value, it can be determined that the temperature of the optical modulation module 120 at a specific position is higher, and therefore the light spot SP is determined to be at the peripheral position of the optical modulation module 120 (as shown in FIG. 2C or FIG. 2D). Then the processing unit 200 responds by performing step S211 to determine whether the highest temperature Ts is greater than the second threshold value Tb2. If not, the intensity of the illumination light beam of the light source module 110 is not reduced, and the process returns to step S200; if so, it means that the panel temperature Tp is too high, and step S220 can be performed to reduce the power of the light source module 110, so as to reduce the intensity of the illumination light beam to avoid excessive temperature of the optical modulation module 120. Step S230 may be further performed to determine whether the highest temperature Ts is greater than the second threshold value Tb2 and the intensity of the illumination light beam of the light source module 110 has been reduced to 0. If not, return to step S200; if so, proceed to step S240, and the processing unit 200 may be adapted to enable the driving component 320 to change the rotation angle or position of the reflecting mirror 310 or the reflecting mirror 311. For the descriptions of relevant steps or methods, reference may be made to the aforementioned step S130 and step S140, which will not be repeated here.

Through the determination process of the embodiment of FIG. 4, it is possible to prevent the processing unit 200 from responding in advance when the light spot SP is at the periphery of the optical modulation module 120, thereby improving the working time and efficiency of the head-up display device 10. Taking Table 1 as an example, when the light spot SP is at the periphery of the optical modulation module 120, the highest temperature Ts sensed at this time is 85 degrees, and the corresponding panel temperature Tp is 90 degrees, which does not exceed the specification temperature of 105 degrees of the optical modulation module 120 and can function normally. However, 85 degrees is substantially equal to the first threshold value Tb1. If there is a slight temperature change or measurement error (for example, 85.1 degrees) at this time, the processing unit 200 will perform the aforementioned steps S120 to S140 to reduce the intensity of the illumination light beam of the light source module 110 or shut down the light source module 110.

Referring to FIG. 1 and Table 1 again, the head-up display device 10 may also include a second temperature sensor 150, which is disposed outside the optical modulation module 120 and configured to sense an ambient temperature Te. The second temperature sensor 150 is electrically connected to the processing unit 200, and the second temperature sensor 150 can transmit the sensed ambient temperature Te to the processing unit 200.

Referring to Table 1, it can be known from experimental or simulated data the highest temperature Ts value and the panel temperature Tp value of the first temperature sensors 140 corresponding to the optical modulation module 120 under different ambient temperatures Te when there is no light spot SP formed on the optical modulation module 120. For example, when the ambient temperature Te is 25 degrees (the unit is Celsius, ° C., represented by Te25 in Table 1) and there is no light spot SP formed on the optical modulation module 120, and the highest temperature Ts is 35 degrees, the corresponding panel temperature Tp is 45 degrees, and the processing unit 200 may set a third threshold value Tb3 to 35 degrees. The processing unit 200 can form different third threshold values Tb3 according to different ambient temperatures Te. The third threshold value Tb3 can be configured to determine whether there is currently a light spot SP formed at the center position of the optical modulation module 120, or whether there is no light spot SP formed on the optical modulation module 120, which can prevent an error from occurring to the processing unit 200 when there is no light beam SP formed on the optical modulation module 120.

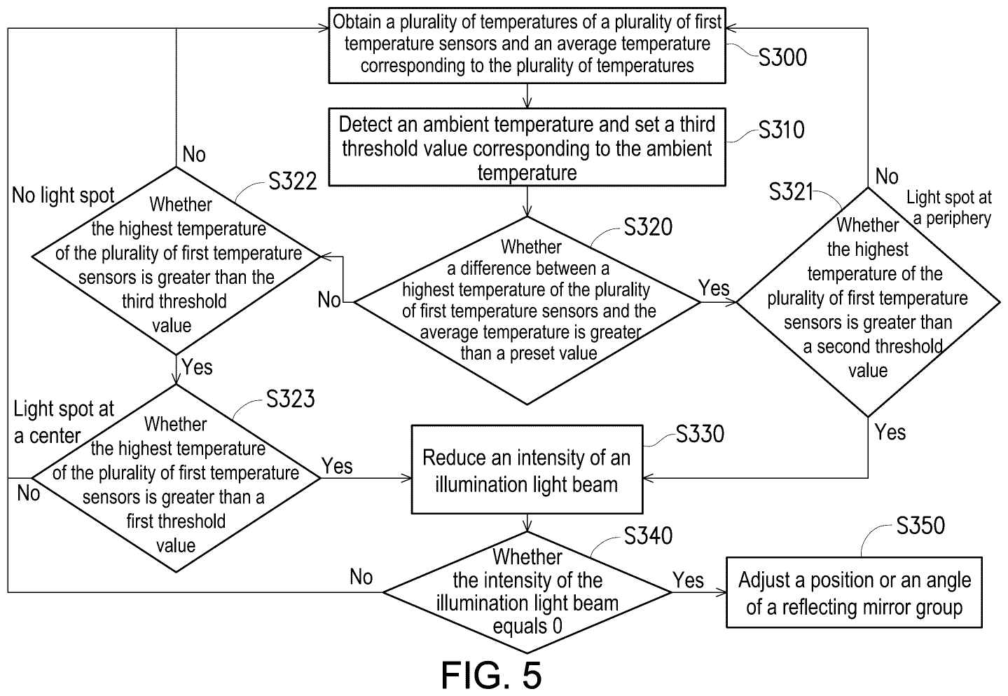

FIG. 5 is a schematic flowchart of a temperature control method of a head-up display device according to yet another embodiment of the disclosure. Referring to Table 1 and FIG. 5 at the same time, in step S300, the processing unit 200 obtains the plurality of temperatures of the plurality of first temperature sensors 140 and obtains an average temperature thereof. In step S310, the ambient temperature Te is detected, and the corresponding third threshold value Tb3 is set according to the ambient temperature Te.

In step S320, the processing unit 200 may determine whether the difference between the highest temperature Ts and the average temperature is greater than the preset value (for example, any temperature from 1 to 10 degrees, the unit is Celsius, ° C.). If not, it means that the plurality of first temperature sensors 140 sense substantially similar temperature values, meaning that the light spot SP is at the center of the optical modulation module 120 (as shown in FIG. 2B) or there is no light spot SP formed on the optical modulation module 120 at this time. The processing unit 200 may respond to this determination by performing step S322 to determine whether the highest temperature Ts is greater than the third threshold value Tb3. If not, it can be determined that there is no light beam SP formed on the optical modulation module 120 at this time, and the intensity of the illumination light beam of the light source module 110 is not reduced, and the process returns to step S300; if so, proceed to step S323 to determine whether the highest temperature Ts is greater than the first threshold value Tb1. If not, it means that the light spot SP is formed at the center of the optical modulation module 120, but the temperature of the optical modulation module 120 is an allowable value, and the process returns to step S300. If so, step S330 is performed to reduce the power of the light source module 110, so as to reduce the intensity of the illumination light beam, so that the optical modulation module 120 can effectively cool down. Step S340 can be further performed to determine whether the intensity of the illumination light beam has been reduced to 0 and the highest temperature Ts is still greater than the first threshold value Tb1. If not, return to step S300; if so, proceed to step S350, and the processing unit 200 may be adapted to enable the driving component 320 to change the rotation angle or position of the reflecting mirror 310 or the reflecting mirror 311. For the descriptions of relevant steps or methods, reference may be made to the aforementioned step S130 and step S140, which will not be repeated here.

In step S320, if the difference between the highest temperature Ts and the average temperature is greater than the preset value, it can be determined that the temperature of the optical modulation module 120 at a specific position is higher, and therefore the light spot SP is determined to be at the peripheral position of the optical modulation module 120 (as shown in FIG. 2C or FIG. 2D). The processing unit 200 responds by performing step S321 to determine whether the highest temperature Ts is greater than the second threshold value Tb2. If not, the intensity of the illumination light beam of the light source module 110 is not reduced, and the process returns to step S300; if so, it means that the panel temperature Tp is too high, and step S330 can be performed to reduce the power of the light source module 110, so as to reduce the intensity of the illumination light beam to avoid excessive temperature of the optical modulation module 120. Step S340 may be further performed to determine whether the highest temperature Ts is greater than the second threshold value Tb2 and the intensity of the illumination light beam has been reduced to 0. If not, return to step S300; if so, proceed to step S350, and the processing unit 200 may be adapted to enable the driving component 320 to change the rotation angle or position of the reflecting mirror 310 or the reflecting mirror 311. For the descriptions of relevant steps or methods, reference may be made to the aforementioned step S130 and step S140, which will not be repeated here.

Through the above-mentioned method of the embodiment of FIG. 5, it is possible to prevent the processing unit 200 from responding in advance when there is no light spot SP formed on the optical modulation module 120. For example, in Table 1, if the specification temperature of the optical modulation module 120 is 105 degrees, and there is no light spot SP formed to the optical modulation module 120, the highest temperature Ts is, for example, 86 degrees, and the panel temperature Tp corresponding to the highest temperature Ts is 96 degrees. The panel temperature Tp meets the working specifications of the optical modulation module 120. At this time, the third threshold value Tb3 corresponding to the highest temperature Ts is, for example, 86 degrees. The highest temperature Ts is not greater than the third threshold value Tb3. The optical modulation module 120 may continue working as described in step S322.

However, without the above-mentioned determination step, the highest temperature Ts (86 degrees) has exceeded the first threshold value Tb1 (for example, the aforementioned 85 degrees), and the processing unit 200 may reduce the intensity of the illumination light beam of the light source module 110 in advance, or shut down the head-up display device 10 in advance by determining that the light spot SP is at the center of the shape of the optical modulation module 120. In other words, the method of the embodiment can reduce misjudgment of the head-up display device 10 and further increase the working time.

To sum up, the head-up display device and the temperature control method thereof of the embodiments of the disclosure have at least one of the following advantages: using the circuit board to surround the optical modulation module, and using the temperature sensors on the circuit board to sense the temperature of the optical modulation module. Compared with the conventional technology that uses infrared sensors, the cost can be significantly reduced, the light path will not be blocked, the size of the device can be reduced, and the temperature of the optical modulation module can be obtained more accurately. On the other hand, since the temperature of the optical modulation module is sensed more accurately, when the temperatures of the first temperature sensors exceed the set threshold value, the light intensity of the light source module can be correspondingly reduced. It can avoid over-protection or malfunction while ensuring the safe operation of the optical modulation module, and also extend the use time of the optical modulation module.

The foregoing description of the preferred embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A head-up display device, comprising a processing unit and an imaging unit, wherein the imaging unit comprises:
a light source module, configured to provide an illumination light beam;
an optical modulation module, located on a transmission path of the illumination light beam configured to convert the illumination light beam into an image light beam;
a circuit board, surrounding the optical modulation module; and
a plurality of first temperature sensors, disposed on the circuit board, wherein the circuit board is electrically connected to the plurality of first temperature sensors and the optical modulation module,
wherein the processing unit is electrically connected to the light source module and the circuit board, the processing unit is configured to obtain a plurality of temperatures of the plurality of first temperature sensors, and when a highest temperature among the plurality of temperatures is greater than a threshold value, the processing unit is adapted to enable the light source module to reduce an intensity of the illumination light beam.

2. The head-up display device according to claim 1, further comprising a reflecting mirror group disposed on a transmission path of the image light beam, wherein the reflecting mirror group comprises at least one reflecting mirror and at least one driving component, the at least one driving component is electrically connected to the processing unit, and the at least one driving component is connected to the at least one reflecting mirror.

3. The head-up display device according to claim 2, wherein when the highest temperature is greater than the threshold value, and the intensity of the illumination light beam is 0, the processing unit is adapted to enable the at least one driving component to change a rotation angle or a position of the at least one reflecting mirror.

4. The head-up display device according to claim 1, wherein the threshold value comprises a first threshold value and a second threshold value, the second threshold value is greater than the first threshold value, the processing unit is further adapted to generate an average temperature according to the plurality of temperatures, and determine whether a difference between the highest temperature and the average temperature is greater than a preset value, and when the difference between the highest temperature and the average temperature is less than or equal to the preset value, and the highest temperature is greater than the first threshold value, the processing unit is adapted to enable the light source module to reduce the intensity of the illumination light beam.

5. The head-up display device according to claim 4, wherein when the difference between the highest temperature and the average temperature is greater than the preset value, and the highest temperature is greater than the second threshold value, the processing unit is adapted to enable the light source module to reduce the intensity of the illumination light beam.

6. The head-up display device according to claim 4, further comprising a second temperature sensor configured to sense an ambient temperature, wherein the second temperature sensor is electrically connected to the processing unit, the threshold value further comprises a third threshold value, and the third threshold value corresponds to the ambient temperature.

7. The head-up display device according to claim 6, wherein when the difference between the highest temperature and the average temperature is less than or equal to the preset value, the processing unit is further adapted to determine whether the highest temperature is greater than the third threshold value, and when the highest temperature is greater than the third threshold value, and the highest temperature is greater than the first threshold value, the processing unit is adapted to enable the light source module to reduce the intensity of the illumination light beam.

8. The head-up display device according to claim 7, wherein when the difference between the highest temperature and the average temperature is less than or equal to the preset value, and the highest temperature is less than the third threshold value, the intensity of the illumination light beam is not reduced.

9. The head-up display device according to claim 1, wherein a shape of the circuit board is an annular square, and the plurality of first temperature sensors are disposed on four sides of the circuit board.

10. The head-up display device according to claim 1, further comprising a case having an opening, wherein the opening exposes at least a portion of the optical modulation module, and the plurality of first temperature sensors are located between the case and the circuit board.

11. A head-up display device according to claim 1, wherein the plurality of first temperature sensors are located between the light source module and the circuit board, or the circuit board is located between the light source module and the plurality of first temperature sensors.

12. A temperature control method of a head-up display device, wherein the head-up display device comprises a processing unit and an imaging unit, the imaging unit comprises a light source module, an optical modulation module, a circuit board, and a plurality of first temperature sensors, the circuit board surrounds the optical modulation module, and the plurality of first temperature sensors are disposed on the circuit board, the method comprising the following steps:
obtaining a plurality of temperatures of the plurality of first temperature sensors by the processing unit, and obtaining a highest temperature from the plurality of temperatures;
in response to the highest temperature being greater than a threshold value, reducing an intensity of an illumination light beam by the light source module; and
in response to the highest temperature being less than or equal to the threshold value, not reducing the intensity of the illumination light beam.

13. The temperature control method of the head-up display device according to claim 12, further comprising the following steps:
in response to the highest temperature being greater than the threshold value, and the intensity of the illumination light beam being 0, changing a rotation angle or a position of at least one reflecting mirror by at least one driving component.

14. The temperature control method of the head-up display device according to claim 12, wherein the threshold value comprises a first threshold value and a second threshold value, and the second threshold value is greater than the first threshold value, the method further comprising the following steps:
generating an average temperature according to the plurality of temperatures, and determining whether a difference between the highest temperature and the average temperature is greater than a preset value by the processing unit;
wherein the step of reducing the intensity of the illumination light beam by the light source module further comprises:
in response to the difference between the highest temperature and the average temperature being less than or equal to the preset value, and the highest temperature being greater than the first threshold value, reducing the intensity of the illumination light beam by the light source module.

15. The temperature control method of the head-up display device according to claim 14, wherein the step of reducing the intensity of the illumination light beam by the light source module further comprises:
in response to the difference between the highest temperature and the average temperature being greater than the preset value, and the highest temperature being greater than the second threshold value, reducing the intensity of the illumination light beam by the light source module.

16. The temperature control method of the head-up display device according to claim 14, wherein the threshold value further comprises a third threshold value, and the third threshold value corresponds to an ambient temperature, the method further comprising the following steps:
determining whether the highest temperature is greater than the third threshold value by the processing unit;
wherein the step of reducing the intensity of the illumination light beam by the light source module further comprises:
in response to the highest temperature being greater than the third threshold value, and the highest temperature being greater than the first threshold value, reducing the intensity of the illumination light beam by the light source module.

17. The temperature control method of the head-up display device according to claim 16, wherein the step of not reducing the intensity of the illumination light beam comprises:
in response to the difference between the highest temperature and the average temperature being less than or equal to the preset value, and the highest temperature being less than the third threshold value, not reducing the intensity of the illumination light beam.
